(19) United States
(12) Patent Application Publication
(10) Pub. No.: US 2011/0156083 A1
(43) Pub. Date: Jun. 30, 2011

(54) Light emission module with high-efficiency light emission and high-efficiency heat dissipation and applications thereof

(75) Inventors: Bily Wang, Hsin-Chu (TW); Feng-Hui Chuang, Hsin-Chu (TW); Wen-Kuei Wu, Hsin-Chu (TW)

(73) Assignee: HARVATEK CORPORATION, Hsin-Chu (TW)

(21) Appl. No.: 12/845,612

(22) Filed: Jul. 28, 2010

(30) Foreign Application Priority Data
Dec. 30, 2009 (TW) 098145992

(51) Int. Cl. H01L 33/62; H05K 1/11

(52) U.S. Cl. 257/99; 174/252; 257/E33.066

(57) ABSTRACT

A light emission module is provided. The light emission module includes a substrate, a plurality of LED chips disposed on the substrate, a fluorescent colloid and a package colloid surrounding the plurality of LED chips. The substrate includes a substrate body and a plurality of chip pads disposed thereon for carrying the LED chips. A plurality of via holes is formed passing through the chip pads and the substrate body to enhance the heat dissipation of the LED chips. The fluorescent colloid and the package colloid both have light guide structures to improve the color stability and the capacity to process the light shape of the light emission module.

### TECHNICAL FIELD

The present disclosure relates to an LED chip package structure, and particularly relates to a light emission module with high-efficiency light emission and high-efficiency heat dissipation and applications thereof.

### BACKGROUND

Light Emitting Diodes (LEDs) are widely used in electronics, most portable backlighting, traffic signals, automotive lighting, and outdoor displays due to the advantages of their long-life span and low power consumption.

Referring to FIG. 12 a typical light emission module 10 using LEDs is shown. The light emission module 10 comprises an LED component 11, a copper foil 12, an insulated conductor material 14 and an aluminum sheet 16. The copper foil 12, the insulated conductor material 14 and the aluminum sheet 16 form a substrate (not labeled) to support the LED component 11 and to dissipate heat generated by the LED component 11. However, the light emission module of this kind has a complicated manufacturing process and limited heat dissipation efficiency, which results in limited light emission efficiency.

A known method for packaging LED chips includes: providing a plurality of packaged LEDs that have been packaged by dispensing; and electrically connecting the plurality of packaged LEDs onto a Printed Circuit Board (PCB) one by one to form a light emission module, such as a light bar. However, the light emission module so formed has lower color stability and poor light shape output.

In addition, current design of circuit layout only allows the LED light bar to be tested as a final product after it is cut off from a mother substrate. This causes lower production efficiency and lower product yield.

### BRIEF DESCRIPTION OF THE DRAWINGS

The components in the drawing are not necessarily drawn to scale, the emphasis instead being placed upon clearly illustrating the principles of the described embodiments. In the drawings, like reference numerals designate corresponding parts throughout various views, and all the views are schematic.

FIG. 1 is a front view of a light emission module according to a first embodiment of the present disclosure.

FIG. 2 is a back view of the light emission module of FIG. 1.

FIG. 3 is a perspective view of a part of the light emission module of FIG. 1.

FIG. 4 is another perspective view of a part of the light emission module of FIG. 1.

FIG. 5 is a side view of the light emission module of FIG. 1, in which via holes are indicated in dashed lines.

FIG. 6 is a front view of a light emission module according to a second embodiment of the present disclosure.

FIG. 7 is a back view of the light emission module of FIG. 6.

FIG. 8 is a front view of a light emission module array, in which electroplated wires are indicated in dashed lines.

FIG. 9 is a back view of the light emission module array of FIG. 8.

FIG. 10a schematically illustrates a structure of a light emission module according to a third embodiment of the present disclosure, in which the light emission module has a light guide structure that may have diffusion or transparent surfaces.

FIG. 10b schematically illustrates a relation between a viewing angle and a luminance of the light emission module of FIG. 10a, in which the light guide structure has a diffusion surface.

FIG. 10c schematically illustrates a relation between a viewing angle and a luminance of the light emission module of FIG. 10a, in which the light guide structure has a transparent surface.

FIGS. 11a-11h schematically illustrate structures of light emission modules according to a fourth to eleventh embodiments of the present disclosure.

FIG. 12 schematically illustrates the structure of a typical light emission module.

FIG. 13 is an exploded view of a light emission device according to the present disclosure, the light emission device comprises one of the light emission modules described above.

FIG. 14 is an exploded view of a display device according to the present disclosure, the display device comprises one of the light emission modules described above.

### DETAILED DESCRIPTION OF EMBODIMENTS

Reference will now be made to the drawings to described exemplary embodiments in detail.

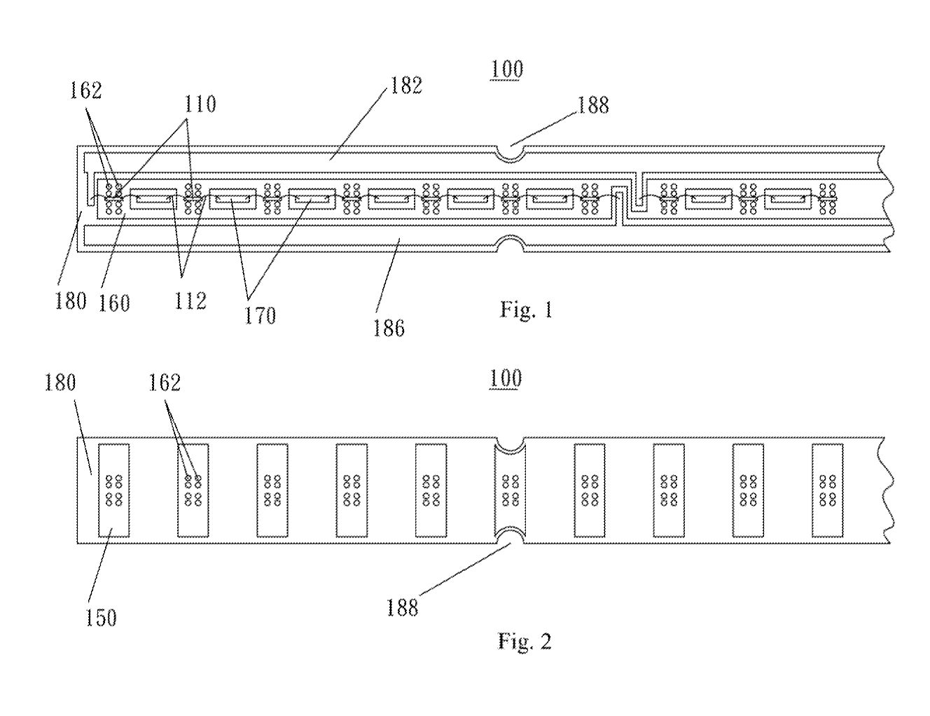

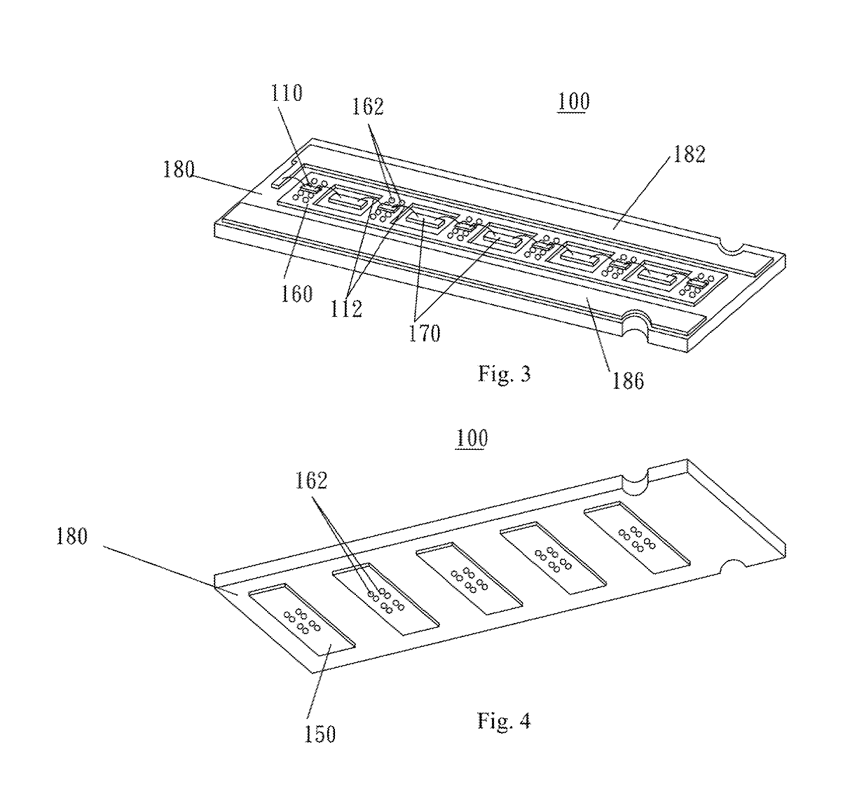

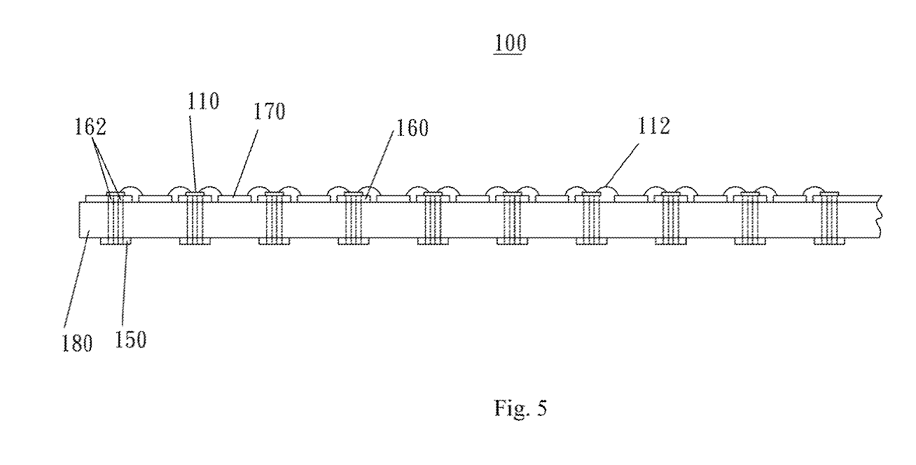

FIGS. 1-5 show different views of a light emission module 100 according to a first embodiment of the present disclosure. The light emission module 100 may comprise a plurality of LED chips 110 and a substrate unit (not labeled). The substrate unit may comprise a substrate body 180, a chip pad 160, a plurality of wire pads 170 and a plurality of heat conductors 150.

In the following description, the side of the substrate body 180 shown in FIG. 1 which is facing the reader (i.e. the front side) is referred to as the first side, and the side opposite to the first side (i.e. the rear side) is the second side. A positive electrode trace 182 and a negative electrode trace 186 are respectively formed on the substrate body 180.

The chip pad 160 and the wire pads 170 are disposed on the first side of the substrate body 180. Pluralities of LED chips 110 are arranged on the chip pad 160 by a matrix method, forming a plurality of longitudinal LED chip rows (only one row showed in FIGS. 1-5). Each LED chip 110 has a positive electrode side and a negative electrode side respectively and electrically connected with the positive electrode trace 182 and the negative electrode trace 186 of the substrate unit through respective wire pad 170 and respective wire 112. The heat conductors 150 are disposed on the second side of the substrate body 180. A plurality of thermal vias 162 is incorporated into the substrate body 180, which link the chip pad 160 and respective heat conductor 150 together, to transfer heat generated by the LED chips 110 from the chip pad 160 to the heat conductor 150. In the illustrated embodiment, no medium is filled in the thermal vias 162.

It should be noted that the drawings only schematically shows a thermal via array with 4 rows and 2 columns formed in the substrate body 180 corresponding to each LED chip 110, and the thermal vias are showed passing through the chip pad 160, the substrate body 180 and the heat conductor 150. In practical, the thermal via array may have different number of rows and columns. Moreover, the thermal vias may only pass through the substrate body 180, but being adjacent to the chip pad 160 and the heat conductor 150.

In the illustrated embodiment, the chip pad 160 and the heat conductor 150 may be made of material of high thermal conductivity, and the substrate body 180 may be made of material known to a person skilled in the art. Because of the incorporation of the thermal vias 162, the heat generated by the LED chips 110 may be transferred from the first side of the substrate body 180 to the second side of the substrate body 180 and then dissipates through the heat conductor 150. Therefore, the substrate unit and the light emission module 100 as shown have sufficiently high heat dissipation performance.

Furthermore, at least one gap 188 may be formed at an edge of the substrate body 180, as shown in FIG. 1. The light emission module 100 may be fastened to a light emission device or a display device by a bolt passing through the gap 188 or by snap fit. The configuration may facilitate the heat dissipation from the heat conductor 150 to the light emission device or the display device. Alternatively, at least one position hole may be formed at a place other than the edge of the substrate body as a substitute for the gap.

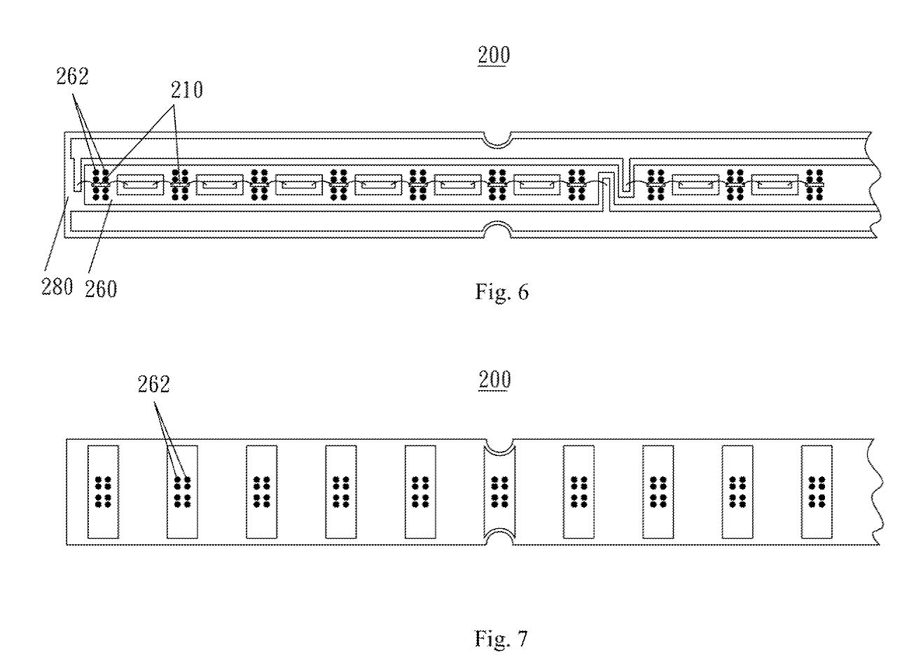

FIGS. 6-7 schematically illustrate a light emission module 200 according to a second embodiment of the present disclosure. Similar to the previously described embodiment, the light emission module 200 also comprises a plurality of LED chips 210, a chip pad 260, a substrate body 280 and a plurality of thermal vias 262. The difference lies in that thermal conductivity material (showed in dark region, not labeled) is filled in the thermal vias 262. The thermal conductivity material may be heat conductive adhesive or heat conductive paste incorporated with metallic component, such as silver paste and copper paste. Thereby, the heat dissipation efficiency of the light emission module 200 is further enhanced due to the filled thermal conductivity material.

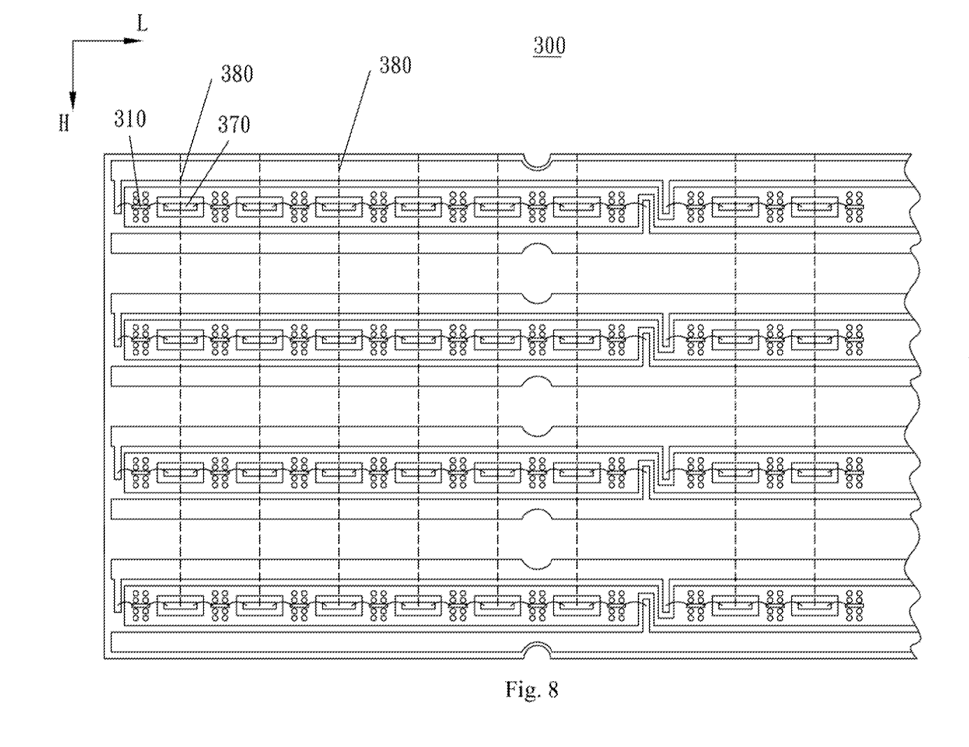

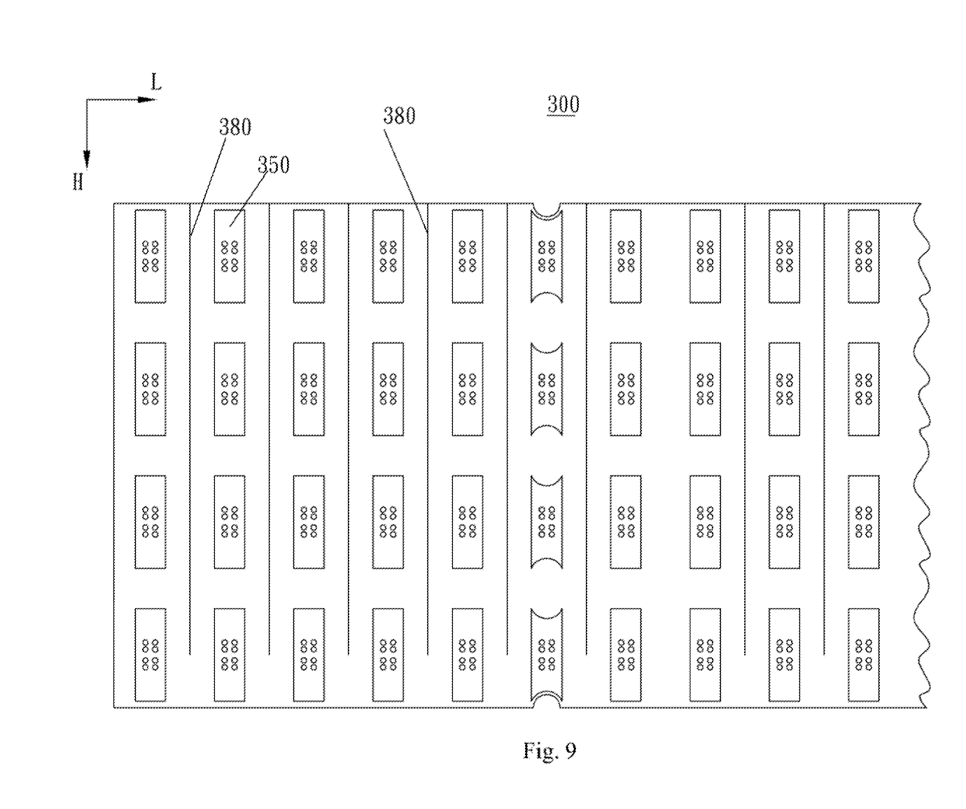

FIGS. 8 and 9 schematically illustrate a light emission module array 300. In the following description, the side of the light emission module array 300 shown in FIG. 8 which is facing the reader is referred to as the front side, and the side opposite to the front side is the rear side (as shown in FIG. 9). A plurality of LED chips 310 and a plurality of wire pads 370 are formed on the front side of the light emission module array 300. A plurality of heat conductors 350 and a plurality of electroplated wires 380 are formed on the rear side of the light emission module array 300. The heat conductors 350 and the electroplated wires 380 are alternately arranged in the direction L, and each electroplated wire 380 extends in the direction H (L, H labeled in FIGS. 8, 9, and the electroplated wires 380 are showed in dashed lines in FIG. 8). That is to say, there is an electroplated wire 380 arranged between every two heat conductors 350. The electroplated wires 380 are electrically connected with corresponding wire pads 370 through respective via holes (not shown) formed in a substrate body of the light emission module array 300.

The electroplated wires 380 are of intermediate products, and they function as an electrode to assist a forming of the wire pad 370 during the plating process. Thereby, the electroplated wire 380 becomes useless after the wire pad 370 is formed. However, for the illustrated configuration, the electroplated wire 380 remain exist until the product is finished, thus the testing problem as mentioned in the background may occur. Since each electroplated wire 380 is kept in electrical connection with respective wire pads 370 arranged in direction H, this may cause a short circuit fault between the wire pads 370 and the electroplated wire 380 when tested. Furthermore, solder mask should be disposed upon electroplated wire 380 for insulation purpose. This causes relatively low heat dissipation.

To overcome the problems mentioned above, a so called “additional etching process” is incorporated herein. The additional etching process is intended to etch the electroplated wires 380 on the light emission module array 300 after the wire pad 370 is formed. This configuration may enable in-line testing during the manufacturing process, and avoid the drawbacks of testing until the product is finished.

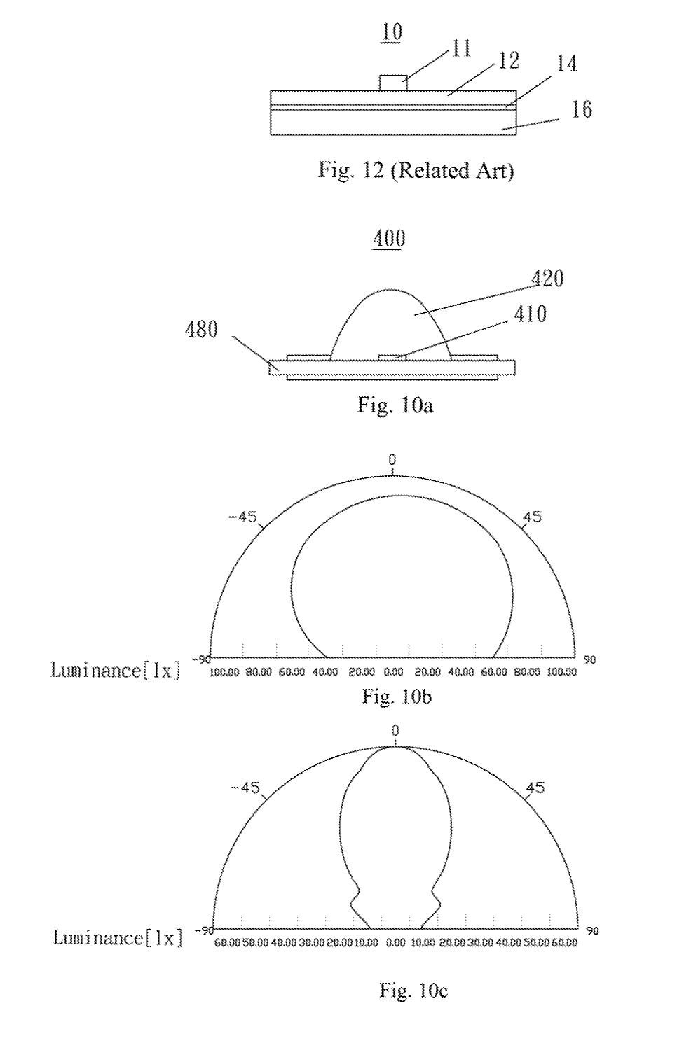

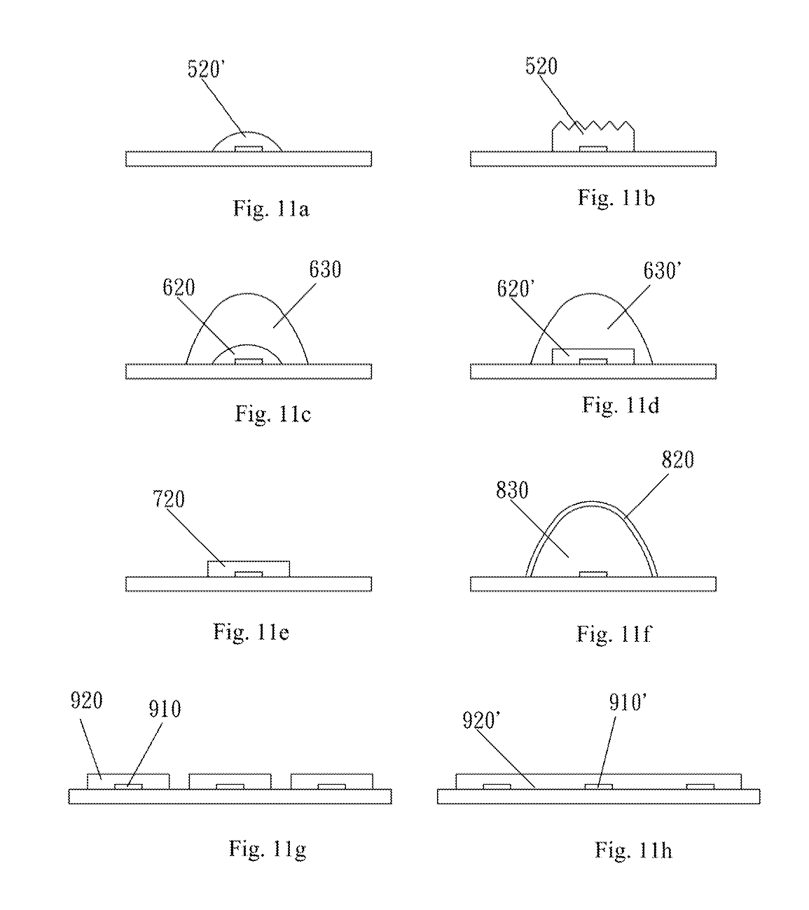

FIG. 10a shows a light emission module 400 according to a third embodiment of the present disclosure. The light emission module 400 may comprise a substrate unit 480, an LED chip 410 disposed on the substrate unit 480, and a package colloid 420 enclosing the LED chip 410. The package colloid 420 comprises an integrally formed light guide structure (not labeled). The light guide structure functions as a lens to guide the light emitted from the LED chip 410 and may have multi-shapes and multi-structures which will be described in detail in the following paragraphs.

The light guide structure of the package colloid 420 may have diffusion or transparent surfaces. The diffusion surfaces may be formed through several methods, for example, by roughing surface of the package colloid 420, by adding impurity such as Titanium Dioxide or fluorescent powder into the package colloid 420, or by forming translucent package colloid 420. The transparent surface may be formed by forming the package colloid 420 into suitable optical lens, for example, a convex lens, a convex-concave lens, or a rod lens.

FIGS. 10b and 10c illustrates a relation between a viewing angle and a luminance of the light emission module 400, in which the light guide structure is of diffusion and transparent surfaces respectively. As seen in FIG. 10b, the diffusion surfaces may allow the directive angle to go up to 180°. Therefore, the light emission module of FIG. 10b is suitable for illuminating applications, such as automotive lighting and outdoor displays. In comparison with the diffusion surface, the transparent surface may concentrate the light emitted from the LED chip 410, and thus narrow the directive angle down to 63°, as shown in FIG. 10c. Therefore, the light emission module of FIG. 10c is suitable for backlighting applications, such as liquid crystal display backlighting.

Referring to FIGS. 11a, 11b, 11e, 11g and 11h, each of the light emission modules showed may have fluorescent colloids. The difference lies in that the configuration of the fluorescent colloids varies in terms of quantity and shapes of the light guide structure. Specifically, the fluorescent colloid 520′ of FIG. 11a has a light concentrating structure which is transparent; the fluorescent colloid 520 of FIG. 11b has a serrate structure; and the fluorescent colloid 720 of FIG. 11e has a plane surface structure. In FIG. 11g, there is a plurality of fluorescent colloids 920 separately disposed on a substrate body and enclosing respective LED chip 910. In FIG. 11h, there is a single fluorescent colloid 920′ disposed on a substrate body and enclosing a plurality of LED chips 910′. The fluorescent colloid 920, 920′ may be formed to enclose the LED chips 910, 910′ by means of dispensing, spraying or molding.

Referring to FIGS. 11c, 11d and 11f, each of the light emission modules showed has both a fluorescent colloid and a package colloid. In FIG. 11c, the package colloid 630 is disposed on the fluorescent colloid 620, and the light guide structure (not labeled) of the fluorescent colloid 620 is arc-shaped. In FIG. 11d, the package colloid 630′ is also disposed on the fluorescent colloid 620′, however, the light guide structure (not labeled) of the fluorescent colloid 620′ is in shape of a plane surface. In FIG. 11f, the fluorescent colloid 820 is disposed on the package colloid 830, and the light guide structures thereof are both arc-shaped.

The above-mentioned embodiments of the light emission module may at least have variation as followings. Firstly, a package colloid may be directly disposed on an LED chip and be configured to have similar light guide structures as showed in FIGS. 11a, 11b and 11e. That is to say, the light guide structure of a package colloid may also have diffusion and/or transparent surfaces. The package colloid may be made of light transparent or light translucent material. The package colloid may be formed by means of dispensing, spraying or molding. Secondly, a package colloid may be directly disposed on an LED chip and have similar configurations as showed in FIGS. 11g and 11h. Furthermore, a combination of the package colloid and the fluorescent colloid may also be configured as showed in FIGS. 11g and 11h.

It should be noted that the inventive aspects of the disclosure are described only with reference to the light emission module. In practice, the above-mentioned disclosure may also be applicable to a light emitting element, a light emission device or a display device. For example, the light emission module with the thermal vias 162 may be used to a light emission device such as a lighting tube or a lighting lamp. Moreover, the above-mentioned light emission module may be combined with a display pane to form a display device, such as a liquid crystal display device (LCD) or a variable message sign (VMS). In addition, the above-mentioned substrate body incorporated with the thermal vias may be used in semiconductor and integrated circuits components in order to improve the heat dissipation efficiency.

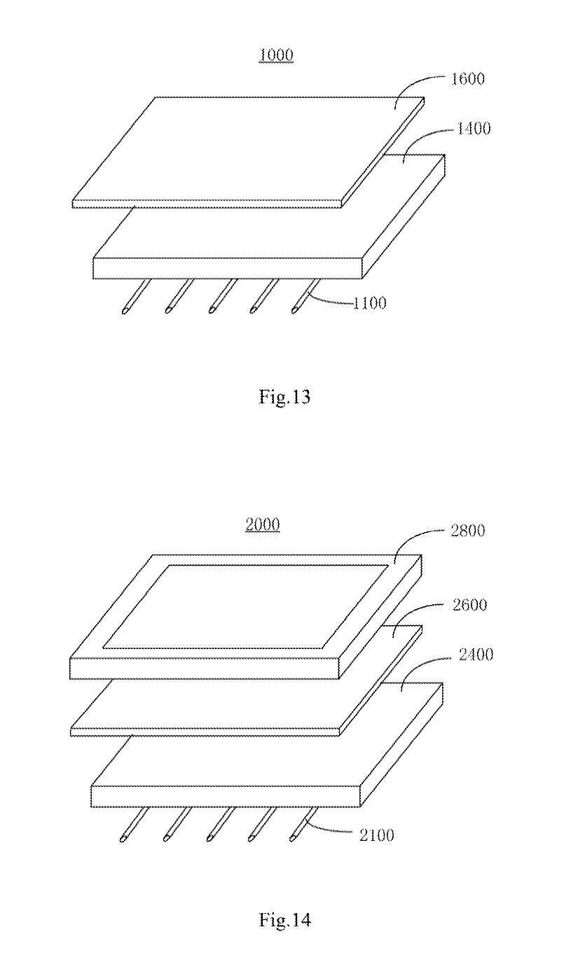

Referring to FIG. 13, a light emitting device 1000 may comprises an optical sheet 1600, a plurality of light emission modules 1100, and a light guide plate (LGP) 1400 disposed therebetween. Each of the light emission modules 1100 may comprise a plurality of LED chips and a substrate unit as mention above (detailed description thereof omitted). The LGP 1400 is adapted to guide light beams provided by the light emission modules 1100 to emit toward the optical sheet 1600. In particular, the LGP 1400 may comprise a bottom surface (not labeled) and a light emitting surface (not labeled) opposite to the bottom surface. The optical sheet 1600 is configured to convert light beams emitting from the LGP 1400 into uniform planar light, and thereby ensuring the lighting quality.

Referring to FIG. 14, a display device 2000 may comprises an optical sheet 2600, a plurality of light emission modules 2100, an LGP 2400 disposed therebetween, and a display panel 2800. Each of the light emission modules 2100 may comprise a plurality of LED chips and a substrate unit as mention above (detailed description thereof omitted). The LGP 2400 is adapted to guide light beams provided by the light emission modules 2100 to emit toward the optical sheet 2600. The optical sheet 2600 is configured to convert light beams emitting from the LGP 2400 into uniform planar light, and thereby ensuring the display quality of the display panel 2800, so as to enable the display panel 2800 to display images.

It is to be understood, however, that even though numerous characteristics and advantages of preferred and exemplary embodiments have been set out in the foregoing description, together with details of the structures and functions of the embodiments, the disclosure is illustrative only; and that changes may be made in detail within the principles of present disclosure to the full extent indicated by the broad general meaning of the terms in which the appended claims are expressed.

What is claimed is:

1. A substrate unit adapted for mounting a light emitting diode chip thereon, the substrate unit comprising:
a substrate body with a first side and a second side opposite to the first side;
an electrode trace being formed on the first side;
a chip pad and a plurality of wire pads disposed on the first side;
a heat conductor disposed on the second side; and
a plurality of thermal vias being incorporated into the substrate body used for dissipating heat, and linking the chip pad and the heat conductor together.

2. The substrate unit of claim 1, wherein thermal conductivity material is filled in the thermal vias.

3. The substrate unit of claim 1, wherein at least one position element is formed on the substrate body, to fasten the substrate unit to an application device.

4. A light emission module, comprising:
at least one light emitting diode chip; and
a substrate unit, comprising:
a substrate body with a first side and a second side opposite to the first side, an electrode trace being formed on the first side;
at least one chip pad and a plurality of wire pads disposed on the first side, the light emitting diode chip being disposed on the chip pad, and the light emitting diode chip being electrically connected with the electrode trace through the wire pads;
at least one heat conductor disposed on the second side; and
a plurality of thermal vias being incorporated into the substrate body, which link the chip pad and the heat conductor together, to transfer the heat generated by the light emitting diode chip from the chip pad to the heat conductor.

5. The light emission module of claim 4, wherein thermal conductivity material is filled in the thermal vias.

6. The light emission module of claim 5, wherein at least one position element is formed on the substrate body, to fasten the substrate unit to an application device.

7. A display device comprising the light emission module as claimed in claim 4.

8. A light emission device, comprising:
at least one light emitting diode chip;
a substrate unit, comprising:
a substrate body with a first side and a second side opposite to the first side, an electrode trace being formed on the first side;
at least one chip pad and a plurality of wire pads disposed on the first side, the light emitting diode chip being disposed on the chip pad, and the light emitting diode chip being electrically connected with the electrode trace through the wire pads;
at least one heat conductor disposed on the second side; and
a plurality of thermal vias being incorporated into the substrate body, which link the chip pad and the heat conductor together, to transfer the heat generated by the light emitting diode chip from the chip pad to the heat conductor;
a light guide plate adapted for guiding the light emitted from the light emitting diode chip; and
an optical sheet configured for converting light beams emitting from the light guide plate into expected light.

9. The light emission device of claim 8, wherein thermal conductivity material is filled in the thermal vias.

10. The light emission device of claim 8, wherein at least one position element is formed on the substrate body, to fasten the substrate unit to the light emission device.
